(19) United States
(12) Patent Application Publication
(10) Pub. No.: US 2011/0132451 A1
(43) Pub. Date: Jun. 9, 2011

(54) SOLDER SUPPORTING LOCATION FOR SOLAR MODULES AND SEMICONDUCTOR DEVICE

(75) Inventors: Hilmar Von Campe, Bad Homburg (DE); Bernd Meidel, Grossheubach (DE); Georg Gries, Mombris (DE); Christoph Will, Kaiserslautern (DE); Jurgen Rossa, Hanau (DE)

(73) Assignee: SCHOTT SOLAR AG, Mainz (DE)

(21) Appl. No.: 13/054,576

(22) PCT Filed: Jul. 16, 2009
(86) PCT No.: PCT/EP2009/059192

§ 371 Date: Feb. 15, 2011

(30) Foreign Application Priority Data
Jul. 18, 2008 (DE) 10 2008 002 954.8

(51) Int. Cl. H01L 31/02; H01L 31/18; B23K 31/02

(52) U.S. Cl. 136/256; 228/180.21

(57) ABSTRACT

A soldered connection between an outer surface of a semiconductor device, connected to a substrate by means of an adhesive layer, and a connector in the form of a strip. In order that tensile forces acting on the connector do not cause the semiconductor device to become detached from the substrate or the adhesive layer, it is proposed that a supporting location extends from the outer surface of the semiconductor device, which supporting location is formed of solderable material and makes contact with the outer surface by way of a contact surface A, in or on which the connector is soldered while maintaining a distance a from the outer surface where a≧10μ; and/or that the distance b between the edge of the contact surface between the supporting surface and the outer surface and the entry of the connector into the supporting location or the beginning of contact therebetween is b≧50μ.

The invention relates to a soldered connection between an outer surface of a semiconductor device and a preferably lamellar connector, particularly between the backside contact of a solar cell and a connector, such as, a series connector. Furthermore, the invention relates to a method for connecting a connector to an outer surface of a semiconductor device, particularly a series connector to a backside contact of a solar cell, where the semiconductor device is connected via an adhesive layer to a substrate.

Known soldered connections between a connector and an amorphous silicon thin film solar cell are characterized by an irreproducible adhesion of the soldering joint.

Investigations with thin film solar cells have frequently yielded a tear off image where the amorphous silicon layer peels from the TCO adhesive layer (Transparent Conductive Oxide). However, it would be a misinterpretation to assume that the adhesive strength on the amorphous silicon layer on the TCO layer would be inhomogeneous to such a high degree. Consequently, corresponding tear off images are explained not by a poor, inhomogeneous layer adhesion, but by the peeling of the layer, which is caused by the substantially more bending resistant soldering joint, in such a way that the tear off force is concentrated on a very small area on the margin of the tear off location, so that very small forces already lead to high surface forces.

WO-A-2006/128203 relates to an electrical connection element which is made of an electrical conductor presenting a structured surface, and of an electrically conducting coating. A corresponding connection element can be used for connecting solar cells. For this purpose, a connection element which presents a solderable coating is soldered to the solar cell.

The object of DE-A-36 12 269 is a method for the application of a connecting conductor to the connection contact of a photovoltaic solar cell.

US-A-2007/0085201 relates to a power semiconductor device in the flat conductor technology with a vertical current path. A connection element is connected to a power semiconductor chip via an electrically conducting film which also connects the connection element electrically to an internal flat conductor.

The present invention is based on the problem of further developing a soldered connection as well as a method for its manufacture in such a way that tensile forces acting on the connector do not lead to the detachment of the semiconductor device from the substrate or from the adhesive layer present between the substrate and the semiconductor device.

According to the invention, the problem is solved by a soldered connection of the type mentioned in the introduction, where, from the outer surface of the semiconductor device, a support location starts, which made of a solderable material and which is in contact with the outer surface via a contact surface A, on or in which support location the conductor is soldered while maintaining a separation a with a≧10 μm from the outer surface, and/or the separation b between the margin of the contact surface between the support surface and the outer surface of the semiconductor device, and the entry of the connector in the support location or the contact beginning between them, is b≧50 μm. Separation b here means that the margin of the contact surface extends at least at a separation of the center of a circle with radius b from the entry or contact beginning, because tensile forces can in principle be distributed over any radial directions.

As a result, a tear off force acting on the connector is uniformly distributed over a large surface.

For example, if the adhesive strength of the semiconductor device on the intermediate layer is 20 N/mm², then, if the support location presents a surface area of 40 mm², a theoretical tear off force of 400 N can be generated, to detach the semiconductor device from a substrate, such as, an adhesive layer. However, before these tear off forces are reached, the connectors that are usually used with solar cells tear. Typical values are between 60 N and 100 N. However, the prerequisite with regard to considerations pertinent to this subject is that the support location keeps adhering to the outer surface, that is, it must not become detached.

In particular, it is provided that the connector always maintains in its area that is connected to the support location the separation a, which should be between 20 μm and 500 μm, particularly between 100 μm and 200 μm. Independently thereof, the separation a must be maintained at least in the area in which the connector is connected in the marginal area to the support location, or in which the connector is immersed in the support location, or in which the contact beginning of the connector to the support location extends. The latter applies particularly to the case where the connector is soldered to the support location.

The separation b should particularly be greater than 100 μm, particularly between 300 μm and 3 mm.

Moreover, the invention provides for the support location to be designed homogeneously, where a preferred thickness to be indicated is 10 μm to 500 μm, particularly in the range between 100 μm and 200 μm. Here, one should ensure that, in the area of the connector and its surroundings, the thickness of the support location does not fall below those values. Otherwise there is a risk that the peeling off starts in the layer system, that is in the area between the support location and the semiconductor device, particularly the solar cell.

By maintaining the separation a between the connector itself, that is without any solder, such as, tin layers or the like, and the outer surface of the semiconductor device on which the support location is applied, one ensures that, when high tensile forces occur, which act on the connector, the peeling is shifted into the support location, that is, the peeling does not occur on the outer surface, but in the contact area between the connector and the support location, that is between the connector and the solderable material, such as, conductive adhesive, sintered conductive paste or solder material. Below, the general term solder or solder material is used for the sake of simplicity.

However, the possibility exists to prevent peeling off, and to produce a tearing off of the connector even at high tearing forces, if, on the connector, a layer, having a thickness of 200 μm to 500 μm, of the solder material that constitutes the soldering joint is soldered, or if the connector is introduced or pressed in a guided way into the support location during the soldering of the connector to the support location, so that the desired separations both from the outer surface of the semiconductor device and also from the outer surface of the support location are maintained. By almost soldering the connector, one achieves that, when using connectors of thickness 100 μm, the tearing off no longer occurs between the connector and the solder, instead the connector itself tears with a tear off force of approximately 60 N.

The usual connectors used for solar cells, which are made from tin-coated copper, present a width from 1 to 5 mm with the indicated thickness of 100 μm.

In particular, it is provided that the semiconductor contact or the semiconductor device itself is connected with an adhesive strength of σ[N/mm²] to a substrate, such as, an adhesive layer, that the connector is destroyable with a tear off force F_{B}[N], and that the contact surface area A [mm²] of the support location is A≧F_{B}/σ. Here, the adhesive strength of the semiconductor device on the substrate or adhesive layer is between 0.7 N/mm² and 200 N/mm², in the case of solar cells.

As solder or solder material one can consider using particularly lead-free tin, or tin with a silver content of up to 3.5 wt %, or Sn alloys with at least one metal element from the group In, Pb, Cd, Bi, Da, Ag, Cu, Si metal, Al, Mg, and Zn.

To achieve defined support location surfaces, a variant provides that the support location is delimited by a ring element made of metal which is connected by means of the solderable material to the outer surface of the semiconductor device. In this case, the surface of the ring element is part of the contact surface of the support location. Alternatively one can use for the defined delimitation of the support location on the outer surface a removable ring element which is preferably made of plastic, and which can be removed after the solidification of the support location.

In particular, the semiconductor device is an amorphous silicon thin film solar cell or a module made from amorphous silicon thin film solar cells, the thin film solar cell is connected with an adhesive strength a of 10 N/mm²≦σ40 N/mm² via a TCO layer to the substrate, such as, a glass panel, the support location is connected via a contact surface A with A≧1 mm², preferably 5 mm² to 70 mm², to the backside contact of the thin film solar cell, and the connector is soldered in the support location or on the support location at separation a from the backside contact with a≧500 μm. The support location presents particularly a contact surface area of 5 mm² to 70 mm².

In particular, it is provided that the contact surface A presents an approximately circular geometry with a diameter d with 5 mm≦d≦7 mm.

The semiconductor device with a wafer thickness of, for example, approximately 100 μm-600 μm can also be a crystalline silicon solar cell. Usually, when tearing off a stable soldering joint, a bending moment is applied to 100 μm to 600 μm, usually 300 μm thick silicon panel, where the panel can already break out at forces of approximately 3 N. To increase the bending moments and to achieve higher pull off forces, which result in either a detachment of the silicon panel from an adhesive layer or a rupturing of the panel itself, it is provided that the solar cell is connected to a substrate via a hard plastic layer, such as, for example, a Surlyn® layer having a thickness between 100 μm and 200 μm.

Independently thereof, the support location can also consist of at least two partial support locations, where the connector in each partial support location maintains the separation a.

A method for connecting a connector to a semiconductor device, particularly a lamellar series connector to a backside contact of a solar cell, where the semiconductor device is connected preferably via an adhesive layer to a substrate, is characterized by the process steps:
application and connection of a solderable material to the outer surface of the semiconductor device to a contact surface having a surface extent A, which is determined as a function of the adhesive strength of the semiconductor device on its substrate and of the tear force causing the tearing of the connector, and
soldering of the connector to or in the solidified solderable material,
where the connector is connected at a separation a with a≧10 μm, preferably a≧20 μm, particularly a≧80 μm from the contact surface to the solderable material. It is preferred that the separation a is 80 μm≦a≦300 μm.

Here it is provided particularly that the solderable material is connected to the outer surface and soldered to it at a temperature T_{L} with T_{L}≦400° C., particularly T_{L}≦300° C. Moreover, the connector should be soldered at a temperature T_{V} with T_{V}≦400° C., particularly T_{V}≦300° C., in or on the solderable material.

To achieve a good connection by material bonding between the solderable material and the outer surface, a variant provides that, before connecting the solderable material to the outer surface, a flux is applied in the area of the contact surface to be formed.

Moreover, the possibility exists, for the purpose of achieving a defined contact surface size, that the contact surface is delimited by the free inner surface of a ring element arranged on the outer surface, which is removed after the solidification of the solderable material, such as, the solder.

The possibility also exists to introduce solderable material into the inner space of a ring element which is arranged on the outer surface and made of metal, and then connect it to the outer surface, for example, by inductive heating. In this case, the ring surface is part of the contact surface.

It is preferred to use, as semiconductor device, an amorphous silicon thin film solar cell which is connected with an adhesive strength between 10 N/mm² and 40 N/mm² to the substrate.

As semiconductor device, one can also use a crystalline silicon solar cell, which is connected to the substrate via a Surlyn® layer, where the thickness of the Surlyn® layer is in the range between 100 μm and 200 μm.

Moreover, it is optionally provided that, above the connector connected to the support location, solder material is applied with a thickness D₁ of 200 μm≦D₁≦500 μm.

However, the scope of the invention also covers the case where the connector is connected to the semiconductor device via several support locations that run along a straight line. However, in a corresponding embodiment, the following secondary condition must be satisfied, namely that, in each individual partial support location, the minimum separation between the surface of the semiconductor device and the connector within or on the partial support location is equal to or greater than a. The partial support surfaces here overall constitute the total contact surface A.

In particular in the case of partial support locations, the possibility also exists that said places are not applied directly on the surface of the semiconductor device, but on an electrically conducting material, such as, for example, a path made of tin. The minimum separation a is then obtained from the separation of the bottom side of the conductor path starting directly from the semiconductor device and the course of connector within each partial support location.

Moreover, for each external partial support location, the separation b between the margin of the conductor path viewed in the longitudinal direction of the latter, and the entry place of the connector into the partial support location, should be between 300 μm and 3 mm, particularly between 300 μm and 1 mm.

Additional details, advantages and characteristics of the invention result not only from the claims, the characteristics to be taken from them—separately and/or in combination—but also from the following description of preferred embodiments:

The figures show:

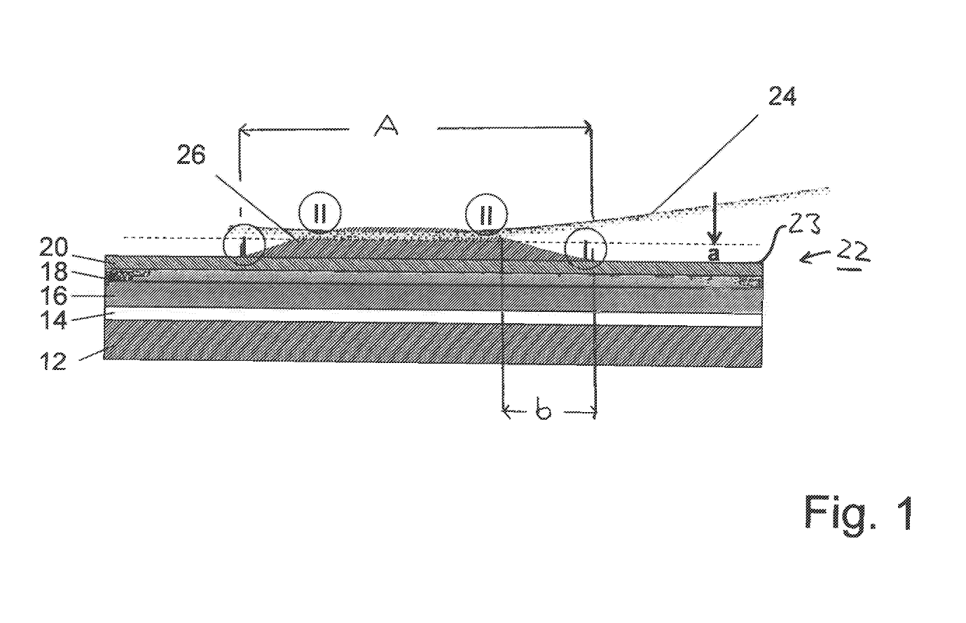

FIG. 1 a schematic diagram of a first embodiment of a solar cell with a support location and a connector,

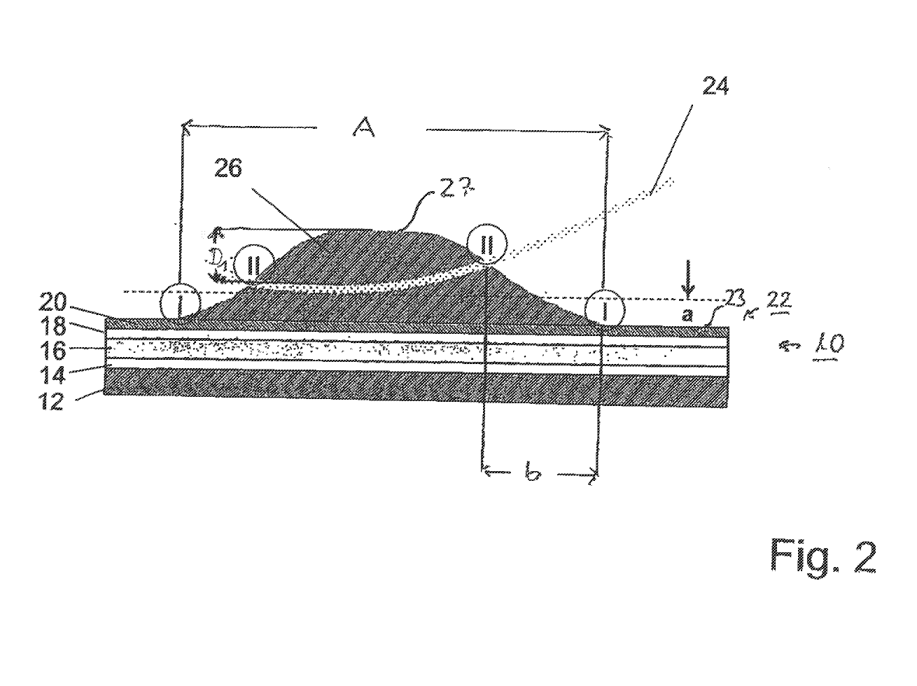

FIG. 2 a schematic diagram of a second embodiment of a solar cell with a support location and a connector,

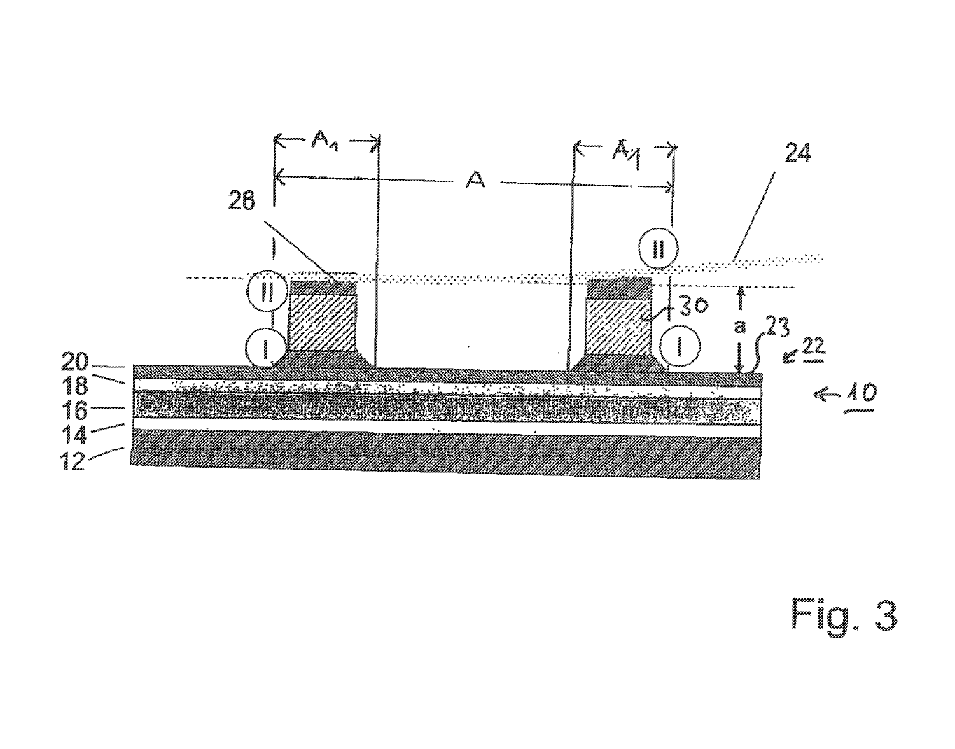

FIG. 3 a schematic diagram of a third embodiment of a solar cell with a support location and a connector,

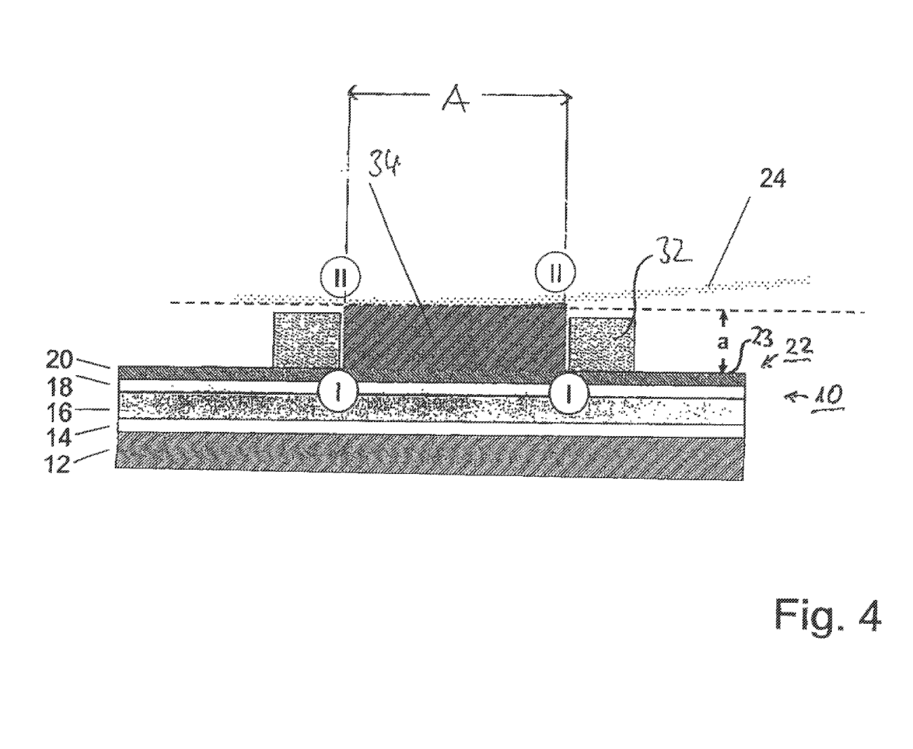

FIG. 4 a schematic diagram of a fourth embodiment of a solar cell with a support location and a connector, and

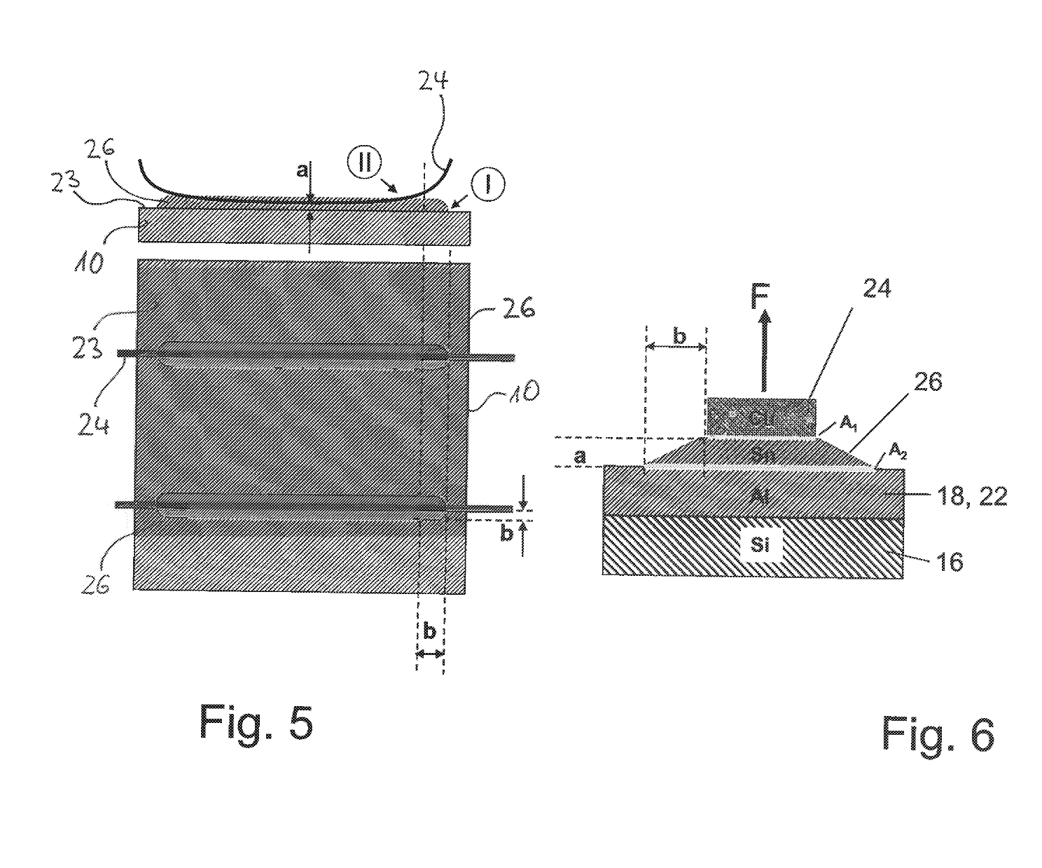

FIG. 5 a top view of an additional embodiment of a solar cell with support locations designed as lamellas,

FIG. 6 a detail of the solar cell according to FIG. 5 in cross section with lamellar support location,

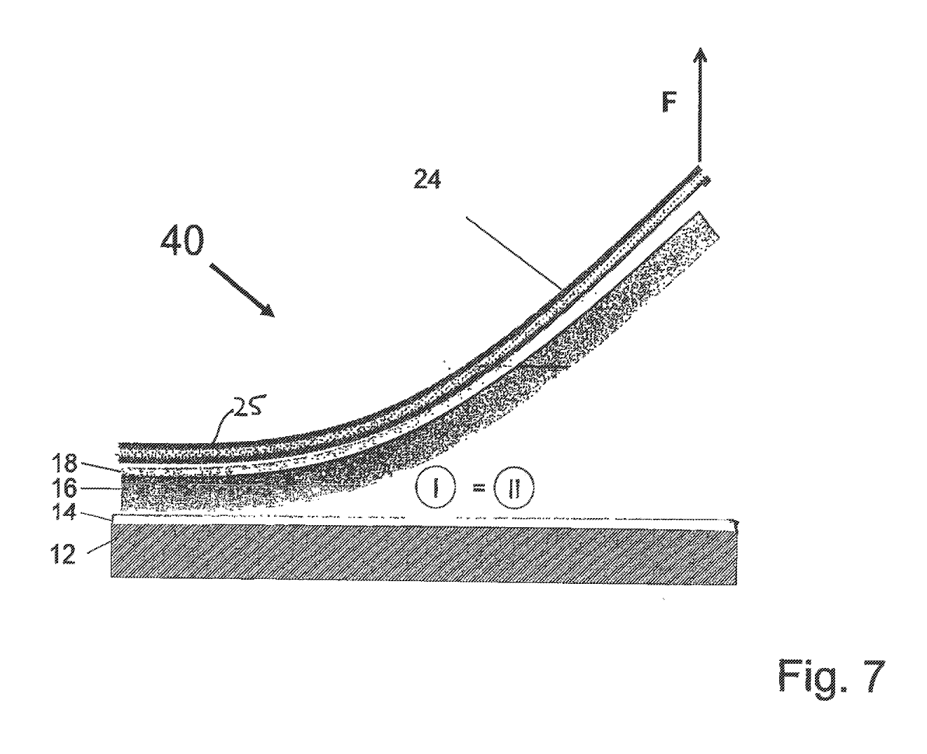

FIG. 7 a schematic diagram of a peeling process,

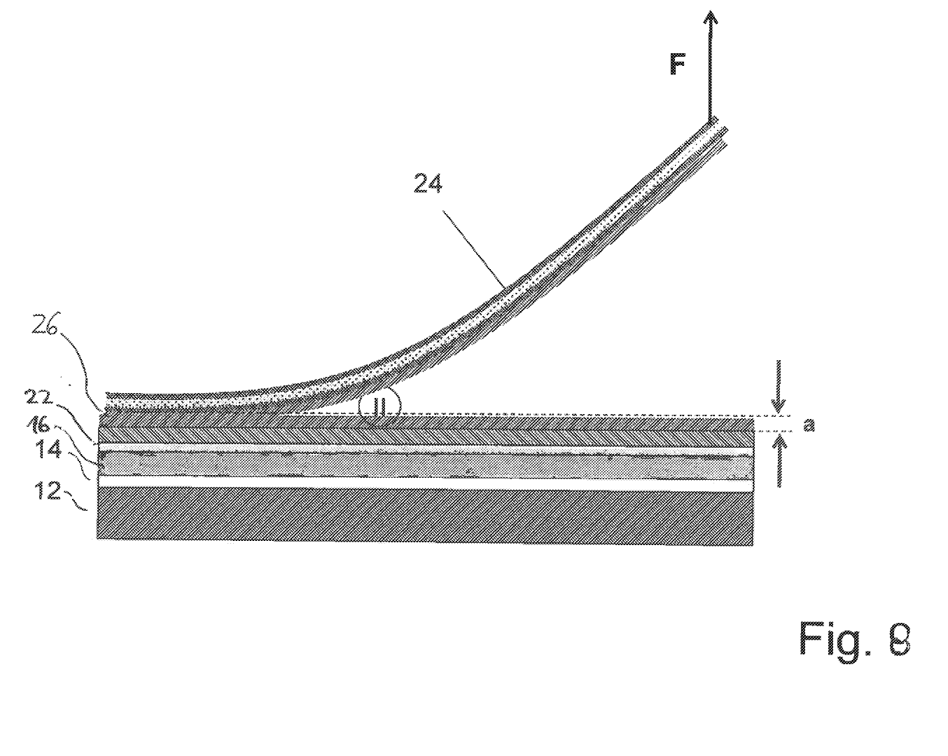

FIG. 8 an additional diagrammatic presentation of a peeling process,

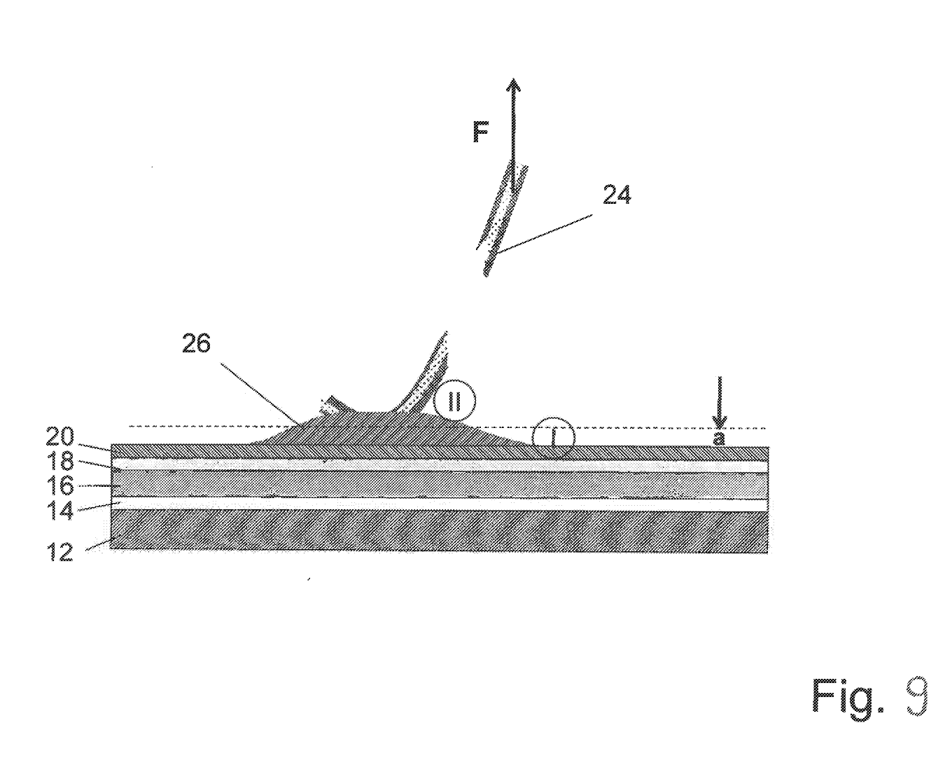

FIG. 9 a schematic diagram of a connector connected to a support location,

FIG. 10 an additional embodiment of a solar cell with a support location consisting of partial support locations,

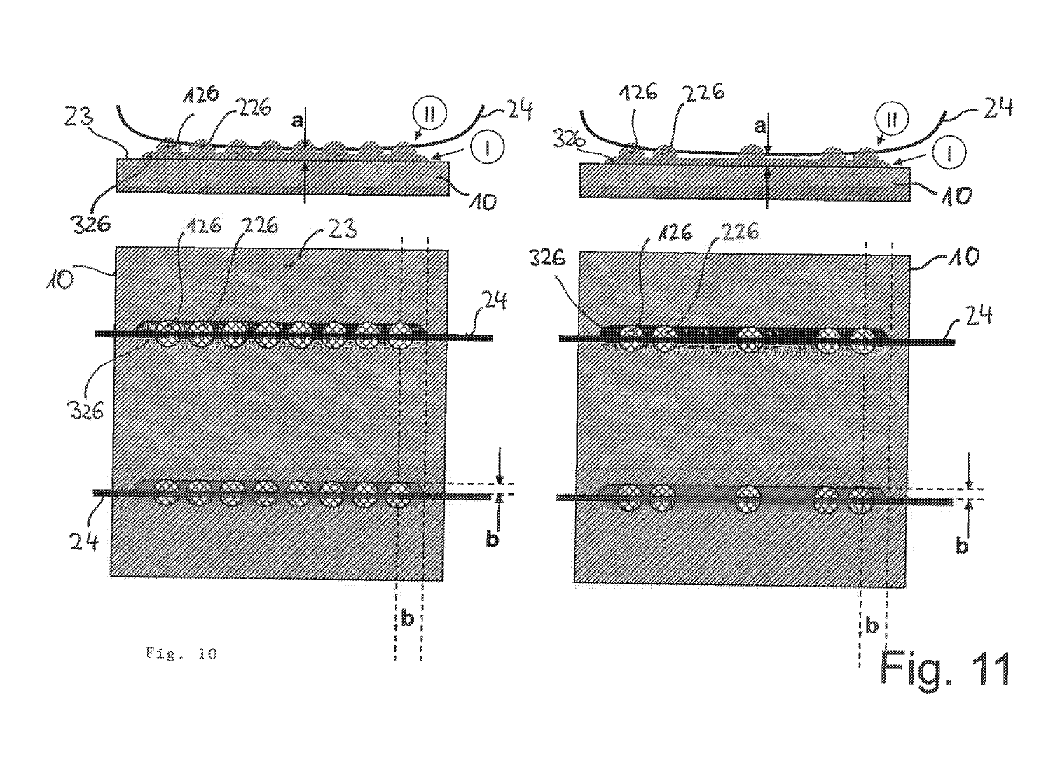

FIG. 11 a variant of the embodiment of FIG. 10, and

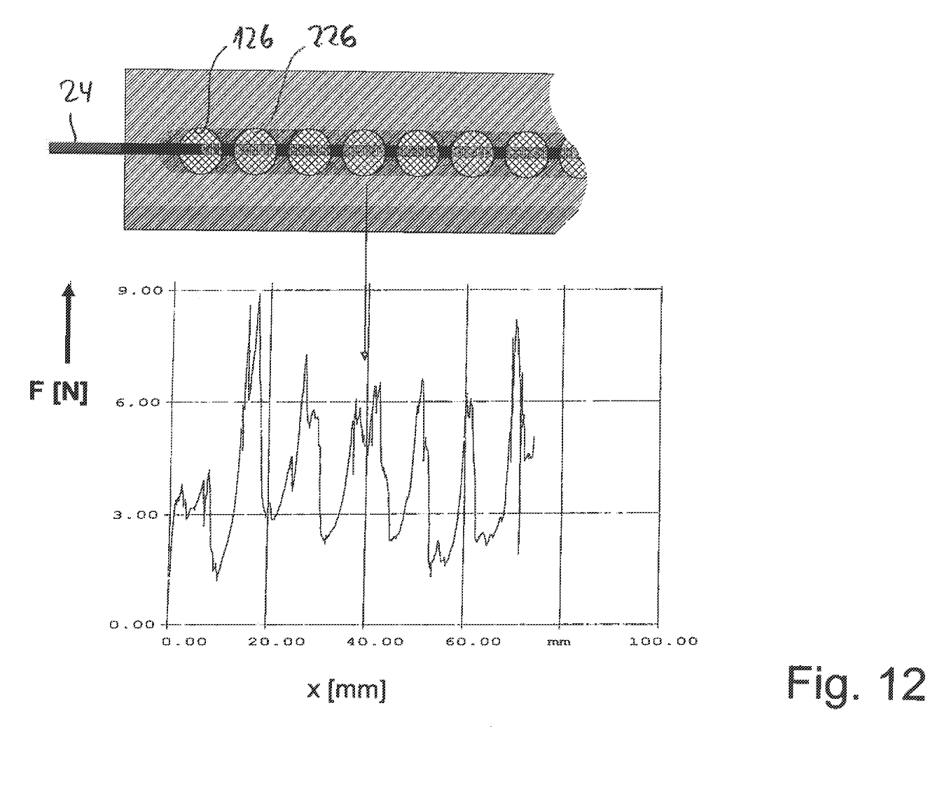

FIG. 12 detachment forces of a connector which is connected via several partial support locations to a solar cell.

In the figures, in which fundamentally identical elements are provided with identical reference numerals, a semiconductor device shown in schematic diagrams is used to explain the teaching according to the invention, that is how to connect a connector to the semiconductor device, in such a way that the tensile forces acting on the connector do not lead to the detachment of the semiconductor device from a substrate, from which the semiconductor device starts, or detachment from an adhesive layer located between the substrate and the semiconductor device.

Thus, the figures show, purely diagrammatically, as semiconductor device, a thin film solar cell 10 made of amorphous silicon. Said cell presents a usual structure, that is, on a glass substrate 12, via a TCO layer 14 (transparent contact) as adhesive layer, a layer system forming a photoactive region and made of amorphous silicon—such as, a p-i-n structure—is arranged, referred to as layer 16 below, which in turn is covered by a backside contact 22. In the embodiment example, the backside contact 22 is made from a metal layer 18, such as, an aluminum layer, or a layer which covers the former layer and made of nickel or a nickel containing (Ni:V) layer 20, in order to allow a soldering to a connector 24 of the type indicated below. Instead of the layer consisting of aluminum, it is possible, for example, to use a silver layer or a silver containing layer as backside contact or as a layer of the latter. Furthermore, a ZnO layer should extend between the layer 16 which made of amorphous silicon and the backside contact 22. The TCO layer 14 often made of SnO₂:F.

In order to connect a corresponding solar cell 10 in a module, it is necessary that the backside contact 22, which in the embodiment example made of the layers 18 and 20, is connected to the connector 24, which is usually a lamellar series connector made of tin-coated copper with a thickness of 100 μm-200 μm and a width of 1 mm to 5 mm.

To prevent that tensile forces acting on the series connector 24 result in the peeling off of a layer, for example, the silicon layer 16 from the TCO layer 14, it is provided, according to the invention, that, on the backside contact 22, that is its outer surface 23, a support location 26 consisting of solder material is applied, and connected to the backside contact 22, where the solder place 26 according to FIGS. 1 and 2 is preferably a lump of solder material, such as, Sn, without limiting the invention to this. Rather, all suitable solderable materials, such as, solder materials, can be considered for use, such as, lead free Sn, Sn with a 3.5 wt % Ag content or Sn alloys with one or more different metal elements from the group Pn, Pb, Cd, Bi, Ga, Ag, Cu, Si metal, Al, Zn, and Mg. For the sake of simplicity, however, reference is made below to an Sn lump as support location 26.

The solder material or solderable material can also be a conductive adhesive or a sintered paste, particularly in the case of thin layer or wafer solar cells that are not based on amorphous silicon.

By applying the Sn lump on the backside contact 22, one achieves that, in the case where tensile forces act on the connector 24, a peeling off in the support location 26 or tearing of the connector 24 occurs, without damage to the photoactive layer 16 occurring. In other words, a tear off place is shifted into the area of the Sn lump, in order to avoid compromising the durability of the thin film solar cell 10.

As a result of the support location 26 or the Sn lump, any forces acting on the series connector 22 are necessarily distributed over a larger surface, that is, the contact surface A between the support location 26 and the outer surface 23 of the backside contact 22. For example, if the adhesive strength a of the layer 16 made of amorphous silicon with respect to the TCO layer 14 is 20 N/mm², then, in the case of a contact surface A of the support location 26 on the backside contact 22 with A=1 mm², tear off forces of 20 N can be applied, without any damage to the silicon layer 16 occurring. If the contact surface A is designed to be, for example, 100 mm², then tear off forces of 2000 N can occur without causing damage to the solar cell 10.

However, with corresponding tear off forces, the series connector 24, which is usually capable of withstanding only tear off forces of up to 60 N, would tear.

The thickness of the Sn lump is designed to be homogeneous, where, in the area in which the series connector 24 is connected to the Sn lump or extends in the latter, the separation a between the backside contact and the series connector should be at least 10 μm, preferably 20 μm to 500 μm, particularly 100 μm to 200 μm. If, in the embodiment example of FIG. 2, the series connector 24 is soldered in the Sn lump, then—as illustrated in FIG. 3—the possibility exists that the series connector 24 is soldered only on the support location 26, or is covered only to a small extent by solder material.

The minimum separation a to be maintained is important, so that the tear off forces are not transferred to the place 1, that is to the peripheral boundary line of the support location with respect to the outer surface 23, that is in the contact area between the Sn lump 26 and the Ni:V layer 20. Otherwise, a peeling off would occur immediately along the outer surface 23, resulting successively in the transfer of the tear off forces over an increasingly smaller contact surface.

By means of the separation a, the tear off or pull off force is distributed over a larger material area, and thus the contact surface is ostensibly increased, so that, even in the case of high tear off or pull off forces, the layer structure of the solar cell is not damaged.

As is apparent from the schematic diagram of FIG. 2, the Sn lump 26 extends with sufficient thickness above the series connector 24. As a result, one achieves that a tearing of the series connector 24 can occur, before a peeling off occurs in the entry area of the series connector into the Sn lump (area II). However, the contact surface between the Sn lump 26 and the surface 23 of the backside contact 22, that is the Ni:V layer 20, must be A≧3 mm², in the case where the force that produces the destruction of the connector 24 is 60 N, and the adhesive strength of the silicon layer 16 with respect to the TCO layer 14 is 20 N/mm². In the case of different values for the adhesive strength, the dimensions of the contact surface A then have to be changed accordingly. The same applies to a tearing force that results in destruction of the series connector 24.

The term “entry area” mentioned above basically refers to an entry place.

To be able to introduce high tear off forces, it is also provided advantageously that the connector 24 is introduced into the Sn lump 26 in such a way that, above the connector 24, solder material extends at a thickness D₁ between 200 μm and 500 μm. The thickness D₁ is the separation between the upper side of the connector 24 and the cone 27 of the support location 26.

The embodiment example of FIG. 1 differs from the one of FIG. 3 in that the connector 24 is connected substantially only to the surface of the Sn lump, that is of the support location 26. Here, the separation a, that is the minimum separation of the connector 24, to the extent its course in the support location 26 is considered, and of the surface 23 of the backside contact 22 should also be at least 10 μm, particularly between 20 μm and 500 μm, where the preferred value range to be indicated is between 100μ and 200 μm.

Independently thereof, the separation between the peripheral boundary line of the Sn lump 26 on the outer surface 23, marked I in the figures, and the entry point or the outer contact point of the connector 24 with the support location 26, marked II in the figures, should be at least 50 μm, preferably at least 100 μm, particularly at least 300 μm, preferably between 300 μm and 3 mm, particularly between 300 μm and 1 mm, although, in principle, there is no upper limit. This separation is marked b in FIGS. 1 and 2. The separation b is measured here along the surface of the contact surface, that is the outer surface 23, and in the pull direction of the connector 24. The pull direction is the direction which acts on the connector 24, where the connector extends as the prolongation of the direction of a section which is connected by material bonding to the soldering support location 26. That is, the separation b between the connector 24 and the contact surface should not be maintained only in the prolongation of the section, but overall in the area of a circle with radius b, which starts from the entry place or the contact beginning of the connector 24 with the support location 26. In FIGS. 5 and 6, the separation b is drawn both in the longitudinal direction of the section and also transversely or perpendicularly to the latter.

The separation b can be different in different radial directions; however, it should be at least 50 μm, particularly at least 100 μm.

FIG. 3 shows an additional embodiment of a support location 28, which consists, for example, of a metal, such as a flat brass ring 30, in whose interior space the solder material, for example, tin, is introduced preferably with a drop of flux. If the annular disk 30 is heated, for example, inductively, the flux and the Sn melt. The solder coats the Ni:V layer 20 and the annular disk 30 to equal measure, and due to capillary action it flows into the gap between the annular disk 30 and the Ni:V layer 20. If soldering of the connector 24 then occurs, for example, by pressing with a soldering head on the annular disk 30, then the solder can no longer flow away. Here, the surface tension by far exceeds the repelling force, so that the solder is no longer displaced. As a result, defined surfaces can be produced, and the separation a between the connection between the series connector 24 and the support location 28 in the solder area 32, and the contact surface A between the solder material and the Ni:V layer 20, is clearly defined. The same geometry can also occur by pressing and sintering an annular conductive paste structure.

The contact area 32 of the series connector 24 on the support location 28 can be referred to as an area II that is at risk for tearing off, and the contact area between the support location 28 and the Ni:V layer 20, as an area I that is at risk for tearing off, analogously to FIGS. 1 and 2. Here, the separation between the areas I and II should be greater than 50 μm, preferably greater than 100 μm, particularly 300 μm, particularly preferably in the range between 300 μm and approximately 3 mm, preferably between 300 μm and 1 mm, so that the application of inadmissibly high pull off forces on the series connector 24 results in a peeling off in the area II that is at risk for tearing off, and not in an area I that is at risk for tearing off. As a result, one succeeds in distributing the pull off forces uniformly over the contact surface A₁ and A₂, in order to thus exclude the mechanisms which occur due to adhesion problems between the silicon layer 16 and the TCO layer 14.

In the embodiment example of FIG. 4, solder is also located in the interior space of the ring element 30. The contact surface in FIG. 4 is correspondingly marked A. If no solder material is located in the inner space of ring 30, the contact surface A₁ is annular (FIG. 3).

By choosing the thickness of the solder material which extends above the series connector 24, as is shown purely diagrammatically in FIG. 2, one achieves—as mentioned—that the series connector 24 itself tears before peeling off occurs in the area II.

Independently thereof, the separation a ensures that no peeling off or tearing off occurs in the contact area with the Ni:V layer 20 (area I), so that the pull off forces transferred to the layer system do not lead to the detachment of the Si layer 14 from the TCO layer 12.

Regarding the tear off mechanism, it should be noted that tearing off occurs in successive, very small steps, and that the effective adhesive force is reduced to a minimum. In the process, infinitesimal tearing off of microscopically small partial surfaces occurs successively. The tearing off forces here are distributed over lines measuring a few mm, which results in a critical adhesive tension.

The embodiment example of FIG. 4 differs from that of FIG. 3 in that a ring 32 consisting particularly of insulating material is positioned on the backside contact 22 at the place where a connection with a connector 24 is to be established. Solder material is then introduced into the interior space of the ring 32, to form a soldering support location 34 which presents correspondingly a disk geometry. Naturally, the possibility also exists to apply a corresponding support location 34 essentially without holding on to it, without the auxiliary ring 32. Independently thereof, the connection of the connector 24 to the support location 34 in terms of dimensions occurs in the above described manner, that is, the separation a between the contact surface or outer surface 23 of the backside contact 22, and at minimal separation of the connector 24 from the surface 23, is at least 10 μm, particularly in the range between 20 μm and 500 μm. The possibility also exists to push the connector 24 into the solder material of the support location 34, to obtain, for example, according to the embodiment example of FIG. 2, above the connector 24, a layer thickness D₁ of solder material in the range between 100 μm and 200 μm.

Based on FIGS. 5-12, the occurring mechanisms will be explained in greater detail as a function of the design or the structure of the support locations, or the course of the connector connected to the latter. Independently thereof, FIGS. 7-9 illustrate that the connectors 24 can be surrounded, for example, by a layer of solder, such as tin. It bears the reference numeral 25 in FIG. 7. The separation a thus relates to the connector 24 itself, and in principle does not take into account the solder layer 25.

Thus, FIG. 5 illustrates that it is not necessarily required that the support surface be designed in the shape of a circle or a spot. Rather, a support location 26 that presents a longitudinal extent can also be used. However, independently thereof, the secondary conditions need to be satisfied, namely that the minimum separation between the connector 24 and the top side 23 of the solar cell 10 is equal to or greater than a with a≧10 μm, particularly 20 μm≦a≦500 μm, preferably 100 μm≦a≦200 μm. Furthermore, one must ensure that the separation b between the outer margin of the support location 26 and the entry point of the connector 24 into the support location 26 is at least approximately 50 μm, preferably at least approximately 100 μm, particularly between 300 μm and 3 mm, preferably between 300 μm and 1 mm.

From FIG. 6, which reproduces a section through a portion of the representation in FIG. 5, one can see that, between the entry place of the connector 24 into the support location 26 and its outer margin on the outer surface 23, there is at least the separation b.

With the aid of FIG. 7, it becomes then clear that, if the connector 24 does not run at a separation a from the surface of the semiconductor substrate in a support location, that is if the areas I and II in accordance with the above explanations coincide, there is a risk that the silicon layer 16 will be peeled off of the TCO layer 14, which damages the solar cell 10.

If, on the other hand, the connector 24 is introduced at the separation a into the support location and if it keeps this separation in the area of the entire support location, where the areas I and II are mutually separated, then, as a function of the occurring pull off forces F, either a peeling off of the support location (FIG. 8) or a tearing of the connector 24 occurs, as shown purely diagrammatically in FIG. 9.

FIGS. 10-12 are intended to illustrate that the support location 26 can consist of several partial support locations 126, 226 which run along a straight line or a line, where the latter places can be arranged on the conducting path, such as, a tin path 326. Here, it is not necessary that the partial support locations 126, 226 present an identical mutual separation.

Independently thereof, however, the secondary condition is satisfied, namely that the connector 24 maintains a separation a in each partial support location 126, 226 with respect to the top side 23 of the solar cell 10, that is the bottom side of the conducting path 326. Furthermore, the separation between the outer margin of the conducting path 326, viewed in the longitudinal direction of the connector 24, that is the area I, and the entry place of the connector 24 into the respective outermost partial support location 126, that is the area II, should be the separation b. The separation a should be at least 10 μm; in particular, it should be between 20 μm and 500 μm, preferably between 100 μm and 200 μm. The separation b is preferably b≧50 μm, and in particular it should be between 300 μm and 3 mm, preferably between 300 μm and 1 mm.

FIG. 12 diagrammatically shows that, if the pull off forces F acting on the connector 24 are excessively high, a successive detachment in the partial support locations 126, 226 occurs, without any peeling off of layers of the solar cell 10 occurring, which would otherwise result in damage to said cell.

1. Soldered connection between an outer surface (23) of a solar cell (10) and a connector (24), particularly between a backside contact (22) of the solar cell and a series connector, where from the outer surface (23) of the solar cell, a support place (26, 28) starts, which is made of a solderable material and in contact via a contact surface A with the outer surface (23), in or on which support place the connector (24) is soldered, while maintaining a separation a from the outer surface,
characterized in that the separation a is a≧10 μm, and the separation b between the margin of the contact surface A between the support surface (26, 28) and the outer surface (23) of the solar cell (10), and the entry of the connector (24) into the support place or the contact beginning between them, is b ≅50 μm.

2. Soldered connection according to claim 1, characterized in that the solar cell (10) is connected via an adhesive layer (14) to a substrate (12).

3. Soldered connection according to claim 1, characterized in that the separation a is 20 μm≦a≦500 μm, preferably 100 μm≦a≦200 μm.

4. Soldered connection according to claim 1, characterized in that the margin of the contact surface on the periphery or outside of the periphery of a circle having a radius that corresponds to the separation b extends starting from the entry place or the contact beginning of the connector (24).

5. Soldered connection according to claim 1, characterized in that, above the connector (24), solder material of the support location (26) extends with a thickness D1 with D1≧200 μm, particularly 200 μm≦D1≦500 μm.

6. Soldered connection according to claim 1, characterized in that the semiconductor device (10) is connected with an adhesive strength σ[N/mm²] to the adhesive layer (14) or the substrate (12), the connector (24) is destroyable with a tearing force F_{B}[N], and the contact surface A between the support location (26) and the outer surface (23) is A≧F_{B}/σ.

7. Soldered connection according to claim 1, characterized in that the adhesive strength s of the semiconductor device is 0.7 N/mm²≦σ≦200 N/mm².

8. Soldered connection according to claim 1, characterized in that the solderable material is industrially pure Sn, Sn with 3.5 wt % Ag, or an Sn alloy with a metal element from the group Pn, Pb, Cd, Bi, Ga, Ag, Cu, Si metal, Al, Mg, and Zn.

9. Soldered connection according to claim 1, characterized in that the contact surface A of the support location (26, 28) is A≧1 mm², particularly 1 mm²≦A≦40 mm².

10. Soldered connection according to claim 1, characterized in that the contact surface A presents an approximately circular geometry with a diameter d with 5 mm≦d≦7 mm.

11. Soldered connection according to claim 1, characterized in that the contact surface A presents an approximately rectangular geometry, preferably with a side length between 2 mm and 6 mm, and 1 mm and 3 mm, respectively.

12. Soldered connection according to claim 1, characterized in that the support location (28) comprises a ring element (30), such as, a perforated disk.

13. Soldered connection according to claim 1, characterized in that the ring element (30) is connected via the solderable material to the outer surface (23) of the semiconductor device (10), and it presents, on its side that is turned away from the semiconductor device, solder material to which the connector (24) is connected.

14. Soldered connection according to claim 1, characterized in that the support location made of at least two partial support locations (126, 226), and the connector (24) in each partial support location maintains the separation (a).

15. Soldered connection according to claim 1, characterized in that the support location comprises at least three partial support locations (126, 226) which are arranged along a straight line or a line.

16. Soldered connection according to claim 1, characterized in that the support location (26) or the partial support locations (126, 226) is/are arranged on a path (326) made of an electrically conducting material.

17. Soldered connection according to claim 1, characterized in that the connector (24), in a first area (II), enters in each case into the outermost support location of the partial support locations (126) arranged along the straight line or the line, the in each case outermost support location is in contact, directly or via the conducting path (326), in a second area (I), with its margin viewed in the direction of the straight line with the semiconductor device (10), and the separation between the first area (I) and the second area (II) is between 300 μm and 3 mm, particularly between 300 μm and 1 mm.

18. Soldered connection according to claim 1, characterized in that the separation b between the margin of the contact surface between the support location (26) and the outer surface (23) of the semiconductor device (10), and the entry of the connector (24) into the support location (26) or the contact beginning between the support location and the soldered on connector, is at least 100 μm, preferably at least 300 μm, particularly between 300 μm and 3 mm, preferably between 300 μm and 1 mm, viewed along the contact surface.

19. Soldered connection according to claim 1, characterized in that the solderable material is a conductive adhesive, a sintered conductive paste or a solder material.

20. Soldered connection according to claim 1, characterized in that the solar cell (10) is a crystalline silicon solar cell, which is connected to a substrate via a plastic layer as adhesive layer, such as, a Surlyn® layer, having a thickness between 100 μm and 200 μm.

21. Solar cell with a soldered connection between an outer surface (23) of a backside contact (22) of the solar cell and a connector (24), where, from the outer surface (23) of the solar cell, a support place (26, 28) starts, which consists of solderable material and which is in contact via a contact surface A with the outer surface, in or on which support place the connector is soldered while maintaining a separation a from the outer surface, where the solar cell is connected via an adhesive layer (14) to a substrate (12),
characterized in that the semiconductor device is an amorphous silicon thin layer solar cell (10) or a module made from amorphous silicon thin layer solar cells, the thin layer solar cell is connected with an adhesive strength σ with 10 N/mm²=σ=40 N/mm² via a TCO layer as the adhesive layer (14) to the substrate, such as, a glass panel (12), the support place (26, 28) is connected via a surface A with A≧1 mm² to the backside contact (22) of the thin layer solar cell, and the connector (24) is soldered in the support place or soldered on the support place at the separation a from the backside surface (23) with a≧20 μm.

22. Solar cell according to claim 21, characterized in that the surface A is 1 mm²≦A≦70 mm², particularly 5 mm²≦A≦70 mm², and the separation a is 100 μm≦a≦200 μm.

23. Method for the connection of a connector (24) with an outer surface (23) of a semiconductor device (10), particularly a series connector, to a backside contact of a solar cell, where the semiconductor device is connected preferably via an adhesive layer (14) to a substrate (12),
characterized by the process steps
application and connection of a solderable material to the outer surface (23) of the semiconductor device (10) with a contact surface having a surface extent (A), which is determined as a function of the adhesive strength (σ) of the semiconductor device on the substrate and of the tear force (F) causing the tearing of the connector, and
soldering of the connector to or in the solidified solderable material,
where the connector is connected at a separation a with a ≧10 μm from the outer surface (23) to the solderable material and/or the separation b between the margin of the contact surface between the support surface and the outer surface of the semiconductor device, and the contact area in which the connector is soldered in or on the support location, is b≧50 μm, viewed in the direction of a tensile force acting on the connector.

24. Method according to claim 23, characterized in that the separation a is a≧20 μm.

25. Method according to claim 23, characterized in that the solder material is applied at the temperature T_{L} with T_{L}≦400° C., particularly with T_{L}≦300° C., to the outer surface.

26. Method according to claim 23, characterized in that the connector (24) is soldered at a temperature T_{V}≦400° C., particularly with T_{V}≦300° C., in or on the solderable material.

27. Method according to claim 23, characterized in that the solderable material is applied together with a flux on the contact surface or outer surface (23) of the semiconductor device (10).

28. Method according to claim 23, characterized in that the contact surface (23) is delimited by a free inner surface of a ring element (30) arranged on the outer surface of the semiconductor device (10).

29. Method according to claim 23, characterized in that the contact surface is delimited by insulation material, such as plastic, for example, solder stop lacquer, applied to the outer surface (23) of the semiconductor device (10).

30. Method according to claim 23, characterized in that the connector (24) is soldered in the solderable material or soldered on the solderable material, with a separation a with a≧10 μm, particularly 20 μm≦a≦500 μm, preferably 100 μm≦a≦200 μm, from the outer surface (23) of the semiconductor device (10).

31. Method according to claim 23, characterized in that the connector is introduced into the solderable material in such a way that, above the connector, solderable material having a thickness D₂ with 200≦D₂≦500 μm extends.

32. Method according to claim 23, characterized in that an amorphous silicon layer of a thin film solar cell is connected, as the semiconductor device, with an adhesive strength σ with 10 N/mm²≦σ≦40 N/mm² via a TCO layer to a glass panel.

33. Method according to claim 23, characterized in that, as semiconductor device, a crystalline silicon solar cell is used which is connected to the substrate via a plastic layer as adhesive layer, such as, a Surlyn® layer.

34. Method according to claim 33, characterized in that the crystalline silicon solar cell is connected to the plastic layer, such as, the Surlyn® layer, having a thickness D with 100 μm≦D≦200 μm to the substrate.
